(19) United States
(12) Patent Application Publication
(10) Pub. No.: US 2025/0381575 A1
(43) Pub. Date: Dec. 18, 2025

(54) SHADOW MASK AND ELECTRONIC DEIVCE MANUFACTURED USING THE SHADOW MASK

(71) Applicant: Samsung Display Co., LTD., Yongin-si (KR)

(72) Inventor: Jin Yong LEE, Yongin-si (KR)

(73) Assignee: Samsung Display Co., LTD., Yongin-si (KR)

(21) Appl. No.: 18/985,711

(22) Filed: Dec. 18, 2024

(30) Foreign Application Priority Data
Jun. 17, 2024 (KR) 10-2024-0078458

(51) Int. Cl. B05B 12/20

(52) U.S. Cl. CPC B05B 12/20

(57) ABSTRACT

A shadow mask includes a lower inorganic layer, a base layer disposed on the lower inorganic layer, a first upper inorganic layer disposed on the base layer, a second upper inorganic layer disposed on the first upper inorganic layer, and an alignment key disposed on the second upper inorganic layer and having a stacked structure of at least four layers in which a low-refractive index inorganic layer and a high-refractive index inorganic layer are alternately stacked each other in a thickness direction of the lower inorganic layer.

### CROSS-REFERENCE TO RELATED APPLICATION(S)

This application claims priority to and the benefits of Korean Patent Application No. 10-2024-0078458 under 35 U.S.C. 119, filed on Jun. 17, 2024, in the Korean Intellectual Property Office (KIPO), the entire contents of which are incorporated herein by reference.

### BACKGROUND

### 1. Technical Field

The disclosure relates to a shadow mask and an electronic device manufactured using the same.

### 2. Description of the Related Art

Shadow masks are used in manufacturing electronic devices (hereinafter referred to as deposition objects) such as display devices. A shadow mask is used to selectively provide a deposition material to a specific area of a deposition object and includes one or more openings.

In case that a deposition object and a shadow mask are misaligned with each other, a problem may occur in which the deposition material is provided to areas other than an intended area of the deposition object.

### SUMMARY

The disclosure provides a shadow mask which is readily aligned with a deposition object.

A shadow mask according to embodiments may include a lower inorganic layer, a base layer disposed on the lower inorganic layer, a first upper inorganic layer disposed on the base layer, a second upper inorganic layer disposed on the first upper inorganic layer, and an alignment key disposed on the second upper inorganic layer and having a stacked structure of at least four layers in which a low-refractive index inorganic layer and a high-refractive index inorganic layer are alternately stacked each other in a thickness direction of the lower inorganic layer.

In one embodiment, a first refractive index of the low-refractive index inorganic layer may be in a range of about 1.3 to about 1.5, and a second refractive index of the high-refractive index inorganic layer may be in a range of about 1.8 to about 2.2.

In one embodiment, the low-refractive index inorganic layer may include silicon oxide, and the high-refractive index inorganic layer may include silicon nitride.

In one embodiment, the low-refractive index inorganic layer and one of the first upper inorganic layer and the second upper inorganic layer may include a same material, and the high-refractive index inorganic layer and another one of the first upper inorganic layer and the second upper inorganic layer may include a same material.

In one embodiment, the low-refractive index inorganic layer and the high-refractive index inorganic layer may satisfy Equation 1:

$$T 1 + T 2 = ( ( 2 N + 1 ) \times {λ}_{0} ) / ( 2 \times ( n 1 + n 2 ) ) \qquad [ Equation 1 ]$$

In Equation 1, T1 may be a thickness of the low-refractive index inorganic layer in the thickness direction, T2 may be a thickness of the high-refractive index inorganic layer in the thickness direction, n1 may be a refractive index of the low-refractive index inorganic layer, n2 may be a refractive index of the high-refractive index inorganic layer, λ₀ may be a wavelength of a visible light in a range of about 400 nm to about 700 nm, and N may be an integer greater than or equal to 0.

In one embodiment, a thickness of the alignment key in the thickness direction may be in a range of about 60% to about 150% of a sum of the thickness of the first upper inorganic layer in the thickness direction and the thickness of the second upper inorganic layer in the thickness direction.

In one embodiment, the shadow mask may further include a first opening passing through the lower inorganic layer and the base layer in the thickness direction, and at least one second opening passing through the first and second upper inorganic layers in the thickness direction.

In one embodiment, the at least one second opening may overlap the first opening in a plan view.

In one embodiment, the first opening may not overlap the alignment key in a plan view.

In one embodiment, the shadow mask may further include a test hole passing through the lower inorganic layer in the thickness direction.

In one embodiment, the test hole may further pass through at least a portion of the base layer in the thickness direction.

A shadow mask according to embodiments may include a lower inorganic layer, a base layer disposed on the lower inorganic layer, a first upper inorganic layer disposed on the base layer, a second upper inorganic layer disposed on the first upper inorganic layer, and an alignment key embedded in a groove defined by the first and second upper inorganic layers and having a stacked structure of at least four layers in which a low-refractive index inorganic layer and a high-refractive index inorganic layer are alternately stacked each other in a thickness direction of the lower inorganic layer.

In one embodiment, a first refractive index of the low-refractive index inorganic layer may be in a range of about 1.3 to about 1.5, and a second refractive index of the high-refractive index inorganic layer may be in a range of about 1.8 to about 2.2.

In one embodiment, the low-refractive index inorganic layer and one of the first upper inorganic layer and the second upper inorganic layer may include a same material, and the high-refractive index inorganic layer and another one of the first upper inorganic layer and the second upper inorganic layer may include a same material.

In one embodiment, the low-refractive index inorganic layer and the high-refractive index inorganic layer may satisfy Equation 1:

$$T 1 + T 2 = ( ( 2 N + 1 ) \times {λ}_{0} ) / ( 2 \times ( n 1 + n 2 ) ) \qquad [ Equation 1 ]$$

In Equation 1, T1 may be a thickness of the low-refractive index inorganic layer in the thickness direction, T2 may be a thickness of the high-refractive index inorganic layer in the thickness direction, n1 may be a refractive index of the low-refractive index inorganic layer, n2 may be a refractive index of the high-refractive index inorganic layer, λ₀ may be a wavelength of a visible light in a range of about 400 nm to about 700 nm, and N may be an integer greater than or equal to 0.

In one embodiment, an upper surface of the alignment key may be aligned with an upper surface of the second upper inorganic layer.

In one embodiment, the shadow mask may further include a first opening passing through the lower inorganic layer and the base layer in the thickness direction, and at least one second opening passing through the first and second upper inorganic layers in the thickness direction.

In one embodiment, the at least one second opening may overlap the first opening in a plan view.

In one embodiment, the shadow mask may further include a test hole passing through the lower inorganic layer in the thickness direction.

In one embodiment, the test hole may further pass through at least a portion of the base layer in the thickness direction.

An electronic device according to embodiments may include a processor to provide input image data, and a display device to display an image based on the input image data. The display device may be manufactured using the shadow mask according to above-described embodiments.

### BRIEF DESCRIPTION OF THE DRAWINGS

FIG. 1 is a plan view for describing a shadow mask of the disclosure.

FIG. 2 is an enlarged plan view of one opening defining area shown in FIG. 1.

FIG. 3 is a schematic cross-sectional view taken along line I1-I2 of FIG. 2.

FIG. 4 is an enlarged plan view of one alignment key shown in FIG. 1.

FIG. 5 is a schematic cross-sectional view taken along line I3-I4 of FIG. 4 for describing an alignment key according to one embodiment of the disclosure.

FIG. 6 is a schematic cross-sectional view taken along line I3-I4 of FIG. 4 for describing an alignment key according to another embodiment of the disclosure.

FIG. 7 is an enlarged plan view of one test hole defining area shown in FIG. 1.

FIG. 8 is a schematic cross-sectional view taken along line I5-I6 in FIG. 7.

FIG. 9 is a schematic cross-sectional view illustrating an operation of aligning the shadow mask of FIG. 1 with a deposition object.

FIG. 10 is a schematic cross-sectional view illustrating a deposition process using the shadow mask of FIG. 1.

FIG. 11 is a schematic block diagram illustrating an electronic device including a display device.

FIG. 12 is a schematic diagram illustrating an embodiment where the electronic device of FIG. 11 is a smartphone.

FIG. 13 is a schematic diagram illustrating an embodiment where the electronic device of FIG. 11 is a tablet computer.

### DETAILED DESCRIPTION OF THE EMBODIMENTS

Hereinafter, embodiments of the disclosure will be described in detail with reference to the attached drawings. In the following description, it should be noted that only portions required for comprehension of operations according to the disclosure will be described and descriptions of other portions will be omitted not to make subject matters of the disclosure obscure. In addition, the disclosure is not limited to the following described embodiments but may also be embodied in other forms. Rather, these embodiments are provided so that the disclosure will be more thorough, and complete, and will fully convey the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing specific embodiments and is not intended to limit the disclosure. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first,” “second,” “third,” and so on may be used herein to describe various elements, these elements are not limited by these terms. These terms are used to distinguish one element from another element. Thus, a first element described below could also be termed as a second or third element without departing from the spirit and scope of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if the device in the drawings is turned over, elements described as “below” or “beneath” other elements or features would then be oriented “above” the other elements or features. Thus, in one embodiment, the exemplary term “below” can encompass both an orientation of above and below. directions. Furthermore, the device may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Various embodiments are described with reference to drawings that schematically illustrate embodiments. Accordingly, it will be expected that the shapes may vary depending, for example, on tolerances and/or manufacturing techniques. Accordingly, the embodiments disclosed herein should not be construed as limited to the specific shapes shown herein, but should be construed to include deviations in shapes that result from, for instance, manufacturing. As such, the shapes shown in the drawings may not depict the actual shapes of regions of the device, and the disclosure is not limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

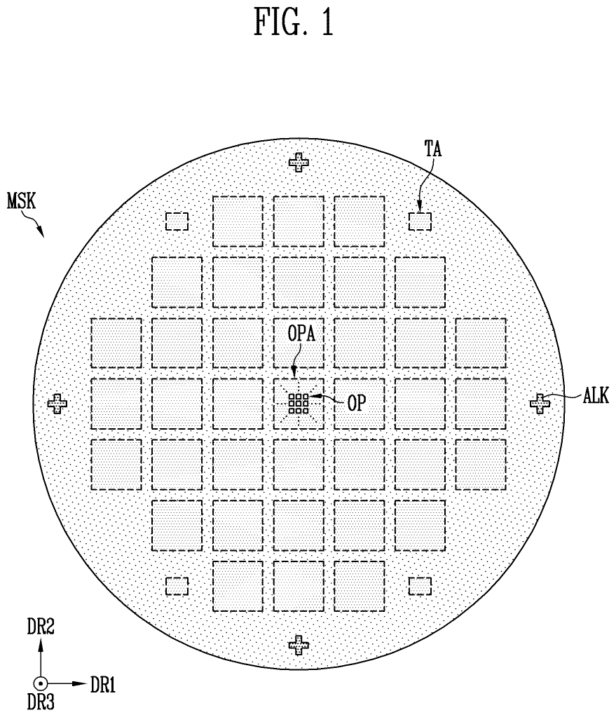

FIG. 1 is a plan view for describing a shadow mask of the disclosure.

Referring to FIG. 1, a shadow mask MSK may be provided. In FIG. 1, a planar shape of the shadow mask MSK is shown as being a circular shape, but the disclosure is not limited thereto. The shadow mask MSK may have various planar shapes (for example, a polygonal shape and an oval shape).

In the specification, the term “plane” may refer to a plane defined by a first direction DR1 and a second direction DR2 intersecting the first direction DR1, and a third direction DR3 perpendicular to the first and second directions DR1 and DR2 may be referred to as a thickness direction.

An opening defining area OPA may be provided in the shadow mask MSK. An opening OP passing through the shadow mask MSK in the thickness direction may be defined in the opening defining area OPA. A deposition material may be provided through the opening OP, and the deposition material may be blocked from other areas, in which the opening OP is not defined, by the shadow mask MSK.

In FIG. 1, the opening OP is illustrated as having a quadrangular shape in a plan view, but the planar shape of the opening OP is not limited thereto. The planar shape of the opening OP may be changed in various ways to correspond to a shape of a specific area of a deposition object to which the deposition material is provided.

Multiple openings OP may be defined in one opening defining area OPA. For example, the openings OP may be arranged in a matrix form in the first direction DR1 and the second direction DR2. However, the arrangement of the openings OP is not limited thereto. The openings OP may be arranged, for example, in a zigzag shape.

Multiple opening defining areas OPA may be provided in the shadow mask MSK. The opening defining areas OPA may be spaced apart from each other by a certain interval. In an embodiment, the openings OP may be defined in each of the opening defining areas OPA.

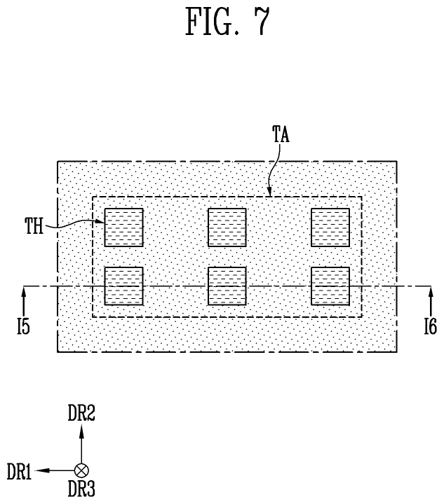

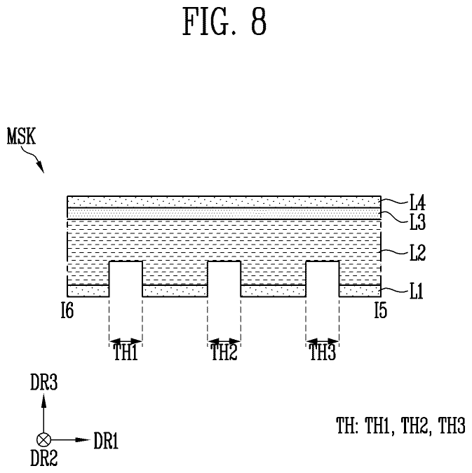

A test hole defining area TA may be provided in the shadow mask MSK. The test hole defining area TA may be provided not to overlap the opening defining area OPA in a plan view. A test hole may be defined in the test hole defining area TA to test whether the deposition material is accurately provided to the deposition object. The test hole may be defined in a rear surface of the shadow mask MSK. FIG. 1 illustrates the test hole defining area TA in which the test hole is formed based on a front surface of the shadow mask MSK. The test hole formed in the rear surface of the shadow mask MSK will be described in detail below with reference to FIGS. 7 and 8.

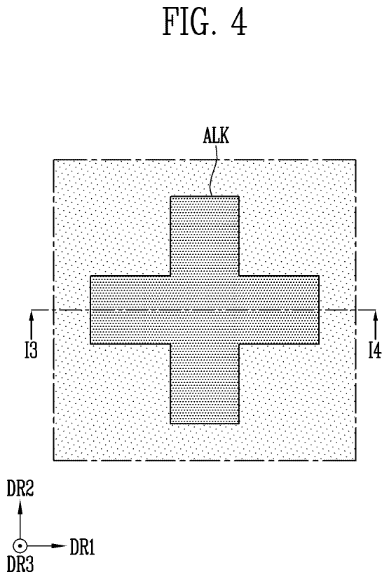

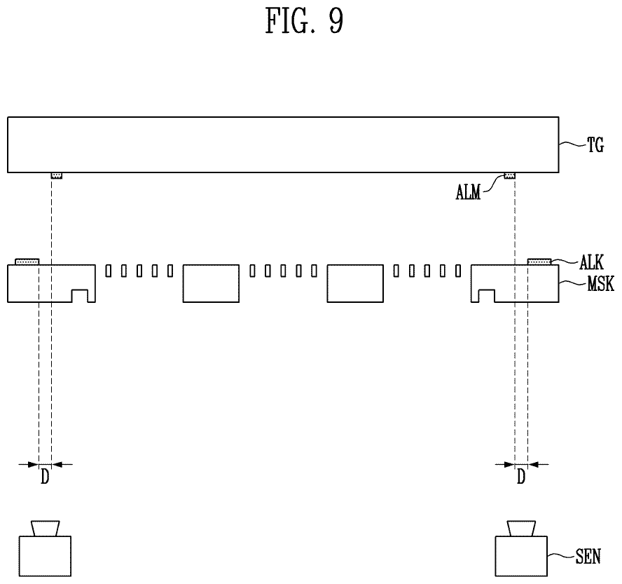

The shadow mask MSK may include an alignment key ALK. The alignment key ALK may not overlap the opening defining area OPA in a plan view. The alignment key ALK may be made of a light-opaque material. For example, the alignment key ALK may have a stacked structure of four or more layers in which low-refractive index inorganic layers and high-refractive index inorganic layers are alternately stacked each other in the third direction DR3. The alignment key ALK will be described in detail below with reference to FIGS. 4 to 6. Relative positions of the deposition object and the shadow mask MSK may be set using the alignment key ALK. For example, the position of the shadow mask MSK may be aligned with the deposition object. This will be described in detail below with reference to FIG. 9.

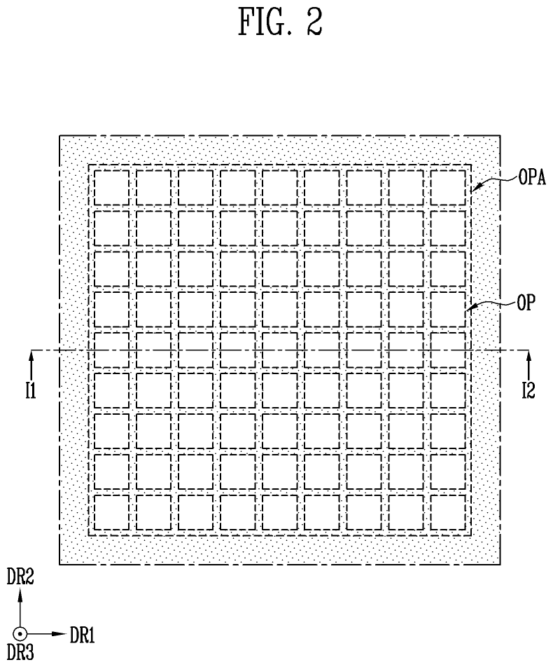

FIG. 2 is an enlarged plan view of one opening defining area shown in FIG. 1.

Referring to FIG. 2, the openings OP may be defined in the opening defining area OPA. FIG. 2 illustrates, for clear and simple description, an embodiment in which 81 openings OP are arranged in a 9×9 matrix form in the first and second directions DR1 and DR2. However, the number and arrangement of openings OP are not limited thereto.

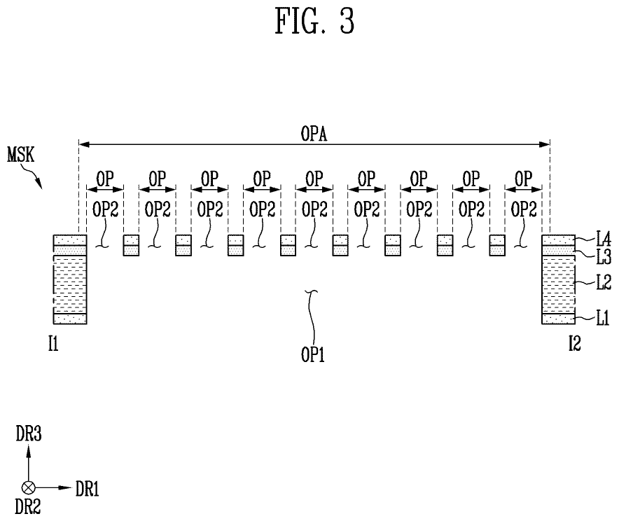

FIG. 3 is a schematic cross-sectional view taken along line I1-I2 of FIG. 2.

Referring to FIGS. 2 and 3, the shadow mask MSK may include a lower inorganic layer L1, a base layer L2, a first upper inorganic layer L3, and a second upper inorganic layer L4.

The lower inorganic layer L1 may include an inorganic insulating material. For example, the lower inorganic layer L1 may include silicon nitride.

The base layer L2 may be disposed on the lower inorganic layer L1. The base layer L2 may be a layer that forms a body of the shadow mask MSK. The base layer L2 may be made of silicon, glass, quartz, or the like. In one embodiment, the base layer L2 may be provided as a silicon substrate made of silicon.

The first upper inorganic layer L3 may be disposed on the base layer L2. The first upper inorganic layer L3 may include an inorganic insulating material. For example, the first upper inorganic layer L3 may include silicon oxide.

The second upper inorganic layer L4 may be disposed on the first upper inorganic layer L3. The second upper inorganic layer L4 may include an inorganic insulating material. For example, the second upper inorganic layer L4 may include silicon nitride.

In the opening defining area OPA, a first opening OP1 passing through the lower inorganic layer L1 and the base layer L2 in the third direction DR3 may be defined. In the opening defining area OPA, one or more second openings OP2 passing through the first and second upper inorganic layers L3 and L4 in the third direction DR3 may be defined. The second openings OP2 may overlap the first opening OP1 in a plan view.

One second opening OP2 and one first opening OP1 overlapping the one second opening OP2 may form one opening OP. The opening OP may be provided to pass through the lower inorganic layer L1, the base layer L2, the first upper inorganic layer L3, and the second upper inorganic layer L4 in the third direction DR3.

FIG. 4 is an enlarged plan view of one alignment key shown in FIG. 1.

FIG. 4 illustrates an embodiment in which the alignment key ALK has a “+” shape in a plan view. However, a planar shape of the alignment key ALK is not limited thereto. The alignment key ALK may have various planar shapes (for example, a circular shape and a polygonal shape) without limitation.

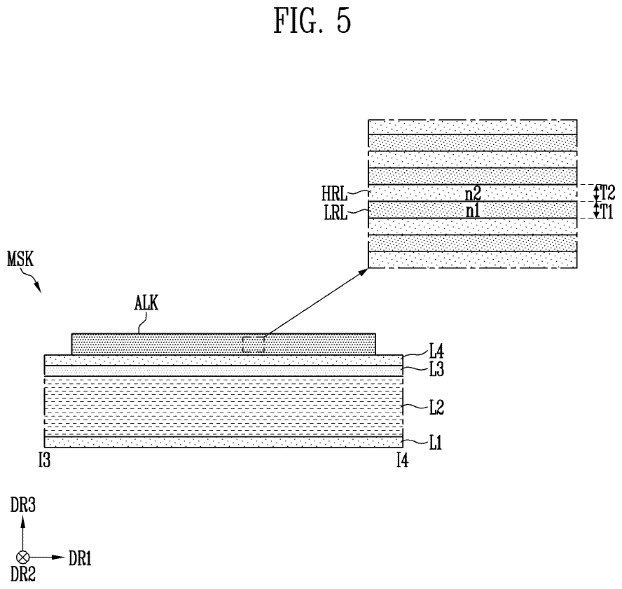

FIG. 5 is a schematic cross-sectional view taken along line I3-I4 of FIG. 4 for describing the alignment key according to one embodiment of the disclosure.

Referring to FIGS. 4 and 5, the alignment key ALK according to one embodiment of the disclosure may be disposed on the second upper inorganic layer L4.

The alignment key ALK may include a low-refractive index inorganic layer LRL and a high-refractive index inorganic layer HRL. The low-refractive index inorganic layer LRL and the high-refractive index inorganic layer HRL may be alternately stacked each other in the third direction DR3. The alignment key ALK may have a stacked structure of four or more layers in which the low-refractive index inorganic layer LRL and the high-refractive index inorganic layer HRL are alternately stacked each other in the third direction DR3.

Due to a difference in refractive index between the low-refractive index inorganic layer LRL and the high-refractive index inorganic layer HRL, Fresnel reflection may occur at an interface between the low-refractive index inorganic layer LRL and the high-refractive index inorganic layer HRL. The alignment key ALK of the disclosure may have a stacked structure of four or more layers in which the low-refractive index inorganic layer LRL and the high-refractive index inorganic layer HRL are alternately stacked each other and thus may not substantially transmit light. Accordingly, in an alignment operation (see FIG. 9) of aligning the shadow mask MSK, the alignment key ALK present on the shadow mask MSK may be readily identified by a sensor SEN (see FIG. 9).

The low-refractive index inorganic layer LRL may have a first refractive index n1. The high-refractive index inorganic layer HRL may have a second refractive index n2. The second refractive index n2 may be greater than the first refractive index n1. In one embodiment, the first refractive index n1 may be in a range of about 1.3 to about 1.5, and the second refractive index n2 may be in a range of about 1.8 to about 2.2.

In one embodiment, the low-refractive index inorganic layer LRL and one of the first and second upper inorganic layers L3 and L4 may include a same material, and the high-refractive index inorganic layer HRL and another one of the first and second upper inorganic layers L3 and L4 may include a same material. For example, the low-refractive index inorganic layer LRL and the first upper inorganic layer L3 may include a same material (for example, silicon oxide), and the high-refractive index inorganic layer HRL and the second upper inorganic layer L4 may be include a same material (for example, silicon nitride).

In an embodiment, the alignment key ALK including the low-refractive index inorganic layer LRL and the high-refractive index inorganic layer HRL and a process of forming the first and second upper inorganic layers L3 and L4 may be formed in substantially the same (or similar) environment. Accordingly, the manufacturing cost of the shadow mask MSK including the alignment key ALK may be reduced, and the reliability of the shadow mask MSK may be further improved.

The low-refractive index inorganic layer LRL may have a first thickness T1 in the third direction DR3. The high-refractive index inorganic layer HRL may have a second thickness T2 in the third direction DR3. Each of the first and second thicknesses T1 and T2 may be less than each of a thickness of the first upper inorganic layer L3 in the third direction DR3 and a thickness of the second upper inorganic layer L4 in the third direction DR3. In one embodiment, the low-refractive index inorganic layer LRL and the high-refractive index inorganic layer HRL may be provided to satisfy Equation 1 below.

$$T 1 + T 2 = ( ( 2 N + 1 ) \times {λ}_{0} ) / ( 2 \times ( n 1 + n 2 ) ) \qquad [ Equation 1 ]$$

In Equation 1 above, T1 may be a thickness of the low-refractive index inorganic layer LRL in the thickness direction DR3, T2 may be a thickness of the high-refractive index inorganic layer HRL in the thickness direction DR3, n1 may be a refractive index of the low-refractive index inorganic layer LRL, n2 may be a refractive index of the high-refractive index inorganic layer HRL, 2 may be a wavelength selected from a visible light wavelength range of 400 nm to 700 nm, and N may be an integer of 0 or more.

In case that the low-refractive index inorganic layer LRL and the high-refractive index inorganic layer HRL are provided to satisfy Equation 1 above, Fresnel reflection may more effectively occur at the interface between the low-refractive index inorganic layer LRL and the high-refractive index inorganic layer HRL. Accordingly, the alignment key ALK may be more readily identified by the sensor SEN (see FIG. 9).

In one embodiment, a thickness of the alignment key ALK in the third direction DR3 may be in a range of about 60% to about 150% of the sum of the thickness of the first upper inorganic layer L3 in the third direction DR3 and the thicknesses of the second upper inorganic layer L4 in the third direction DR3.

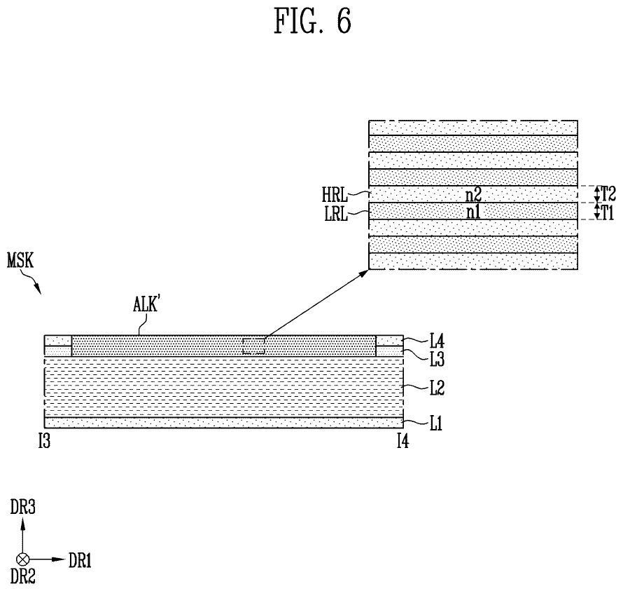

FIG. 6 is a schematic cross-sectional view taken along line I3-I4 of FIG. 4 for describing an alignment key according to another embodiment of the disclosure.

Hereinafter, differences from the embodiment described with reference to FIG. 5 will be described, and the contents omitted from the description will be replaced with the previous contents.

Referring to FIGS. 4 and 6, an alignment key ALK′ may be embedded in a groove defined in the first and second upper inorganic layers L3 and L4. For example, unlike the alignment key ALK described with reference to FIG. 5, the alignment key ALK′ of FIG. 6 may be provided not to protrude from an upper surface of the second upper inorganic layer L4 in the third direction DR3.

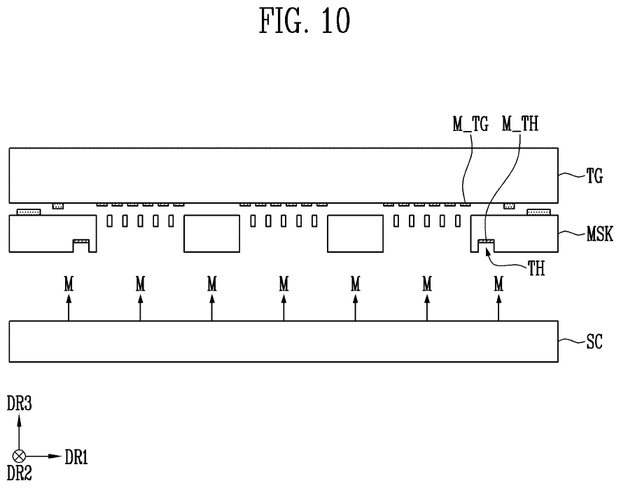

In one embodiment, an upper surface of the alignment key ALK′ may be aligned with the upper surface of the second upper inorganic layer L4. For example, in an area in which the alignment key ALK′ is provided, an upper surface of the shadow mask MSK may be substantially flat. In case that a deposition process using the shadow mask MSK (see FIG. 10) is performed, a deposition object TG may be prevented from being damaged by the alignment key ALK′ of the shadow mask MSK.

FIG. 7 is an enlarged plan view of one test hole defining area shown in FIG. 1.

Referring to FIG. 7, the rear surface of the shadow mask MSK is shown. A test hole TH may be defined in the test hole defining area TA. In the deposition process using the shadow mask MSK (see FIG. 10), a deposition material may be deposited not only in a deposition area of a deposition object but also in the test hole TH. For example, an optical test such as ellipsometry may be performed on the deposition material deposited in the test hole TH. In this way, a test may be performed on the deposition material deposited in the test hole TH, thereby identifying whether the deposition material is accurately deposited on the deposition object. For example, it may be possible to identify whether the deposition material is accurately deposited to a designed thickness or whether the deposition material is deposited to a thickness that is less than or greater than the designed thickness.

The area and shape of the test hole TH in a plan view may be set such that the deposition material may be effectively deposited in the test hole TH. For example, the test hole TH may be provided in a rectangular shape with a width of about 300 micrometers in the first direction DR1 and a width of about 300 micrometers in the second direction DR2.

In case that different types of deposition materials are used in a deposition process using the shadow mask MSK, multiple test holes TH may be formed. For example, in case that six deposition materials are used, six test holes TH may be formed as shown in FIG. 7. The different types of deposition materials may be deposited in the six test holes TH. Accordingly, a test may be performed on each of the test holes TH, thereby identifying whether each of the different types of deposition materials is accurately deposited.

FIG. 8 is a schematic cross-sectional view taken along line I5-I6 in FIG. 7.

Referring to FIGS. 7 and 8, first to third test holes TH1, TH2, and TH3 among the test holes TH are shown.

The test hole TH may pass through the lower inorganic layer L1 in the third direction DR3. According to embodiments, as shown in FIG. 8, the test hole TH may further pass through at least a portion of the base layer L2 in the third direction DR3. In an embodiment, the test hole TH may not completely pass through the shadow mask MSK.

The first to third test holes TH1, TH2, and TH3 may be formed to test different types of deposition materials. For example, while a series of deposition processes using the shadow mask MSK are performed, a first deposition material may be deposited in the first test hole TH1, a second deposition material may be deposited in the second test hole TH2, and a third deposition material may be deposited in the third test hole TH3. In an embodiment, after the deposition processes are performed, a first test may be performed on the first deposition material in the first test hole TH1, a second test may be performed on the second deposition material in the second test hole TH2, and a third test may be performed on the third deposition material in the third test hole TH3.

FIG. 9 is a schematic cross-sectional view illustrating an operation of aligning the shadow mask of FIG. 1 with a deposition object. Hereinafter, descriptions of contents that overlap the contents described with reference to FIGS. 1 to 8 may be omitted.

Referring to FIG. 9, an operation of aligning the shadow mask MSK with the deposition object TG is shown.

The deposition object TG may include an alignment mark ALM. The alignment mark ALM may be light-opaque and may be made of, for example, a metal material.

The sensor SEN may recognize the alignment mark ALM of the deposition object TG and the alignment key ALK of the shadow mask MSK. For example, in case that the sensor SEN is provided as a camera or the like, the light-opaque alignment mark ALM and the alignment key ALK may be displayed relatively dark on an image obtained from the sensor SEN. On the image, a relative position of the shadow mask MSK may be set by identify a relative distance D between the alignment mark ALM and the alignment key ALK. In other words, the shadow mask MSK may be aligned.

FIG. 10 is a schematic cross-sectional view illustrating a deposition process using the shadow mask of FIG. 1. Hereinafter, descriptions of contents that overlap the contents described with reference to FIGS. 1 to 8 may be omitted.

Referring to FIG. 10, after the operation of the aligning described with reference to FIG. 9 is performed, a deposition process of providing a deposition material M from a deposition source SC may be performed. The shadow mask MSK may serve to selectively provide the deposition material M to an area of the deposition object TG, and a first deposition material M_TG may be deposited on the area of the deposition object TG.

At the same time, the deposition material M may be provided in the test hole TH of the shadow mask MSK, and a second deposition material M_TH may be deposited in the test hole TH.

Since the first deposition material M_TG and the second deposition material M_TH are deposited substantially simultaneously through a same deposition process, thicknesses or the like of the first deposition material M_TG and the second deposition material M_TH may be substantially the same. Accordingly, a test result for the second deposition material M_TH may represent a test result for the first deposition material M_TG.

After a deposition process is performed, an optical test such as ellipsometry may be performed on the second deposition material M_TH to measure a thickness of the second deposition material M_TH in the third direction DR3. In an embodiment, the thickness of the second deposition material M_TH and a thickness of the first deposition material M_TG in the third direction DR3 may be substantially the same. Therefore, by using the shadow mask MSK of the disclosure, even a destructive inspection may not be performed on the deposition object TG, and information about the thickness or the like of the first deposition material M_TG deposited on the deposition object TG may be identified.

According to a shadow mask of the disclosure, due to a difference in refractive index between a low-refractive index inorganic layer and a high-refractive index inorganic layer which constitute an alignment key, Fresnel reflection may occur at an interface between the low-refractive index inorganic layer and the high-refractive index inorganic layer. The alignment key may have a stacked structure of four or more layers in which a low-refractive index inorganic layer and a high-refractive index inorganic layer are alternately laminated and thus may not substantially transmit light. Accordingly, in an alignment operation of aligning the shadow mask, the alignment key present on the shadow mask may be readily identified.

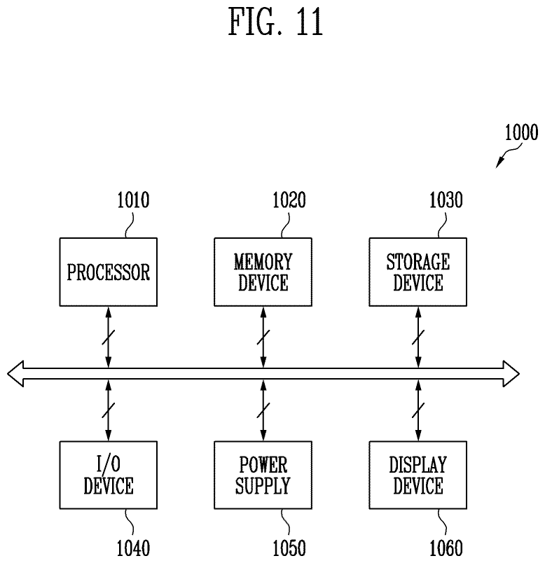

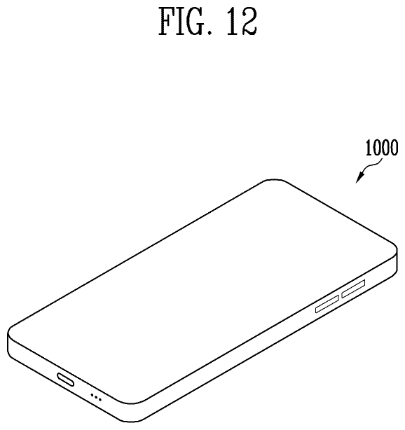

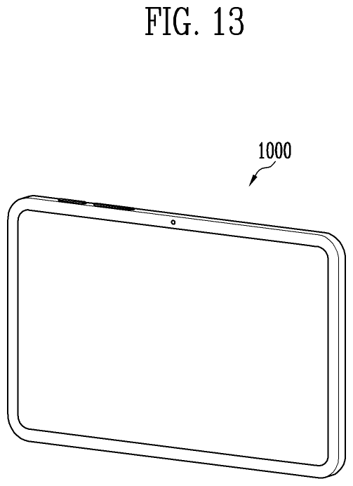

FIG. 11 is a schematic block diagram illustrating an electronic device including a display device. FIG. 12 is a schematic diagram illustrating an embodiment where the electronic device of FIG. 11 is a smartphone. FIG. 13 is a schematic diagram illustrating an embodiment where the electronic device of FIG. 11 is a tablet computer.

Referring to FIGS. 11 to 13, an electronic device 1000 may include a processor 1010, a memory device 1020, a storage device 1030, an input/output (I/O) device 1040, a power supply 1050, and a display device 1060. The display device 1060 may be manufactured using the shadow mask MSK described with reference to FIGS. 1 to 10. The electronic device 1000 may further include various ports for communication with a video card, a sound card, a memory card, a USB device, or other systems. In an embodiment, as illustrated in FIG. 20, the electronic device 1000 may be a smartphone. In an embodiment, as illustrated in FIG. 21, the electronic device 1000 may be a tablet computer. However, the aforementioned embodiments are illustrative, and the electronic device 1000 is not necessarily limited to the aforementioned embodiments. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through the buses or other communication links.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A shadow mask comprising:
a lower inorganic layer;
a base layer disposed on the lower inorganic layer;
a first upper inorganic layer disposed on the base layer;
a second upper inorganic layer disposed on the first upper inorganic layer; and
an alignment key disposed on the second upper inorganic layer and having a stacked structure of at least four layers in which a low-refractive index inorganic layer and a high-refractive index inorganic layer are alternately stacked each other in a thickness direction of the lower inorganic layer.

2. The shadow mask of claim 1, wherein
a first refractive index of the low-refractive index inorganic layer is in a range of about 1.3 to about 1.5, and
a second refractive index of the high-refractive index inorganic layer is in a range of about 1.8 to about 2.2.

3. The shadow mask of claim 2, wherein
the low-refractive index inorganic layer includes silicon oxide, and
the high-refractive index inorganic layer includes silicon nitride.

4. The shadow mask of claim 1, wherein
the low-refractive index inorganic layer and one of the first upper inorganic layer and the second upper inorganic layer include a same material, and
the high-refractive index inorganic layer and another one of the first upper inorganic layer and the second upper inorganic layer include a same material.

5. The shadow mask of claim 1, wherein
the low-refractive index inorganic layer and the high-refractive index inorganic layer satisfy Equation 1:
$$T 1 + T 2 = ( ( 2 N + 1 ) \times {λ}_{0} ) / ( 2 \times ( n 1 + n 2 ) ) \qquad [ Equation 1 ]$$
wherein, in Equation 1,
T1 is a thickness of the low-refractive index inorganic layer in the thickness direction,
T2 is a thickness of the high-refractive index inorganic layer in the thickness direction,
n1 is a refractive index of the low-refractive index inorganic layer,
n2 is a refractive index of the high-refractive index inorganic layer,
λ₀ is a wavelength of a visible light in a range of about 400 nm to about 700 nm, and
N is an integer greater than or equal to 0.

6. The shadow mask of claim 5, wherein a thickness of the alignment key in the thickness direction is in a range of about 60% to about 150% of a sum of the thickness of the first upper inorganic layer in the thickness direction and the thickness of the second upper inorganic layer in the thickness direction.

7. The shadow mask of claim 1, further comprising:
a first opening passing through the lower inorganic layer and the base layer in the thickness direction; and
at least one second opening passing through the first and second upper inorganic layers in the thickness direction.

8. The shadow mask of claim 7, wherein the at least one second opening overlaps the first opening in a plan view.

9. The shadow mask of claim 8, wherein the first opening does not overlap the alignment key in a plan view.

10. The shadow mask of claim 1, further comprising:
a test hole passing through the lower inorganic layer in the thickness direction.

11. The shadow mask of claim 10, wherein the test hole further passes through at least a portion of the base layer in the thickness direction.

12. A shadow mask comprising:
a lower inorganic layer;
a base layer disposed on the lower inorganic layer;
a first upper inorganic layer disposed on the base layer;
a second upper inorganic layer disposed on the first upper inorganic layer; and
an alignment key embedded in a groove defined by the first and second upper inorganic layers and having a stacked structure of at least four layers in which a low-refractive index inorganic layer and a high-refractive index inorganic layer are alternately stacked each other in a thickness direction of the lower inorganic layer.

13. The shadow mask of claim 12, wherein
a first refractive index of the low-refractive index inorganic layer is in a range of about 1.3 to about 1.5, and
a second refractive index of the high-refractive index inorganic layer is in a range of about 1.8 to about 2.2.

14. The shadow mask of claim 12, wherein
the low-refractive index inorganic layer and one of the first upper inorganic layer and the second upper inorganic layer include a same material, and
the high-refractive index inorganic layer and another one of the first upper inorganic layer and the second upper inorganic layer include a same material.

15. The shadow mask of claim 12, wherein
the low-refractive index inorganic layer and the high-refractive index inorganic layer satisfy Equation 1:
$$T 1 + T 2 = ( ( 2 N + 1 ) \times {λ}_{0} ) / ( 2 \times ( n 1 + n 2 ) ) \qquad [ Equation 1 ]$$
wherein, in Equation 1,
T1 is a thickness of the low-refractive index inorganic layer in the thickness direction,
T2 is a thickness of the high-refractive index inorganic layer in the thickness direction,
n1 is a refractive index of the low-refractive index inorganic layer,
n2 is a refractive index of the high-refractive index inorganic layer,
λ₀ is a wavelength of a visible light in a range of about 400 nm to about 700 nm, and
N is an integer greater than or equal to 0.

16. The shadow mask of claim 15, wherein an upper surface of the alignment key is aligned with an upper surface of the second upper inorganic layer.

17. The shadow mask of claim 12, further comprising:
a first opening passing through the lower inorganic layer and the base layer in the thickness direction; and
at least one second opening passing through the first and second upper inorganic layers in the thickness direction.

18. The shadow mask of claim 17, wherein the at least one second opening overlaps the first opening in a plan view.

19. The shadow mask of claim 12, further comprising:
a test hole passing through the lower inorganic layer in the thickness direction.

20. The shadow mask of claim 19, wherein the test hole further passes through at least a portion of the base layer in the thickness direction.

21. An electronic device comprising:
a processor to provide input image data; and
a display device to display an image based on the input image data,
wherein the display device is manufactured using the shadow mask of claim 1.
